(19) United States
(12) Patent Application Publication
(10) Pub. No.: US 2025/0098331 A1
(43) Pub. Date: Mar. 20, 2025

(54) WIDE BANDGAP SEMICONDUCTOR DEVICE

(71) Applicant: FUJI ELECTRIC CO., LTD., Kawasaki-shi (JP)

(72) Inventor: Katsunori UENO, Matsumoto-city (JP)

(73) Assignee: FUJI ELECTRIC CO., LTD., Kawasaki-shi (JP)

(21) Appl. No.: 18/782,379

(22) Filed: Jul. 24, 2024

(30) Foreign Application Priority Data
Sep. 15, 2023 (JP) 2023-149954

(51) Int. Cl. H01L 27/02; H01L 27/088; H01L 29/16; H01L 29/20; H01L 29/49; H01L 29/78

(52) U.S. Cl. CPC H10D 89/817; H10D 30/65; H10D 30/66; H10D 84/83; H10D 62/8325; H10D 62/8503; H10D 64/665; H10D 64/667

(57) ABSTRACT

Provided is a wide bandgap semiconductor device having a configuration capable of detecting a temperature of a substrate with high accuracy during operation of a main transistor. The wide bandgap semiconductor device includes: a substrate mainly including a wide bandgap semiconductor; a vertical MOSFET serving as a main transistor provided in a first region of the substrate; and a lateral MOSFET for temperature detection provided in a second region of the substrate.

### CROSS-REFERENCE TO RELATED APPLICATION

This application claims benefit of priority under 35 USC 119 based on Japanese Patent Application No. 2023-149954 filed on Sep. 15, 2023, the entire contents of which are incorporated by reference herein.

### BACKGROUND OF THE INVENTION

### 1. Field of the Invention

The present disclosure relates to wide bandgap semiconductor devices.

### 2. Description of the Related Art

WO2017/208734A1 discloses a semiconductor device including a main semiconductor element and a temperature sensing part that are provided on a common silicon carbide substrate. The temperature sensing part included in the semiconductor device disclosed in WO2017/208734A1 is a polysilicon diode, for example, including a p-type polysilicon layer and an n-type polysilicon layer provided on the front surface of the silicon carbide substrate.

A main transistor provided on a wide bandgap semiconductor substrate sometimes causes light with a short wavelength during operation. The light, when entering a polysilicon diode for temperature detection, may cause wrong signals because polysilicon has a narrow band gap, which could further lead to a reduction in accuracy of temperature detection. The wide bandgap semiconductor, particularly when including a gallium nitride (GaN), is a direct-transition semiconductor and has a wider bandgap than silicon carbide (SiC), and thus emits stronger light with a shorter wavelength than SiC, having a serious influence on the operation accordingly.

### SUMMARY OF THE INVENTION

In view of the foregoing problems, the present disclosure provides a wide bandgap semiconductor device having a configuration capable of detecting a temperature of a substrate with high accuracy during operation of a main transistor.

To solve the problems described above, a wide bandgap semiconductor device according to an aspect of the present disclosure includes a substrate mainly including a wide bandgap semiconductor, a vertical MOSFET serving as a main transistor provided in a first region of the substrate, and a lateral MOSFET for temperature detection provided in a second region of the substrate.

### BRIEF DESCRIPTION OF THE DRAWINGS

FIG. 1 is a plan view illustrating a configuration example of a GaN semiconductor device according to a first embodiment of the present disclosure;

FIG. 2 is a cross-sectional view illustrating the configuration example of the GaN semiconductor device according to the first embodiment of the present disclosure;

FIG. 3 is a circuit diagram illustrating the configuration example of the GaN semiconductor device according to the first embodiment of the present disclosure;

FIG. 4 is a graph showing an example of temperature dependence of I-V characteristics in a linear region of a lateral MOSFET for temperature detection;

FIG. 5 is a circuit diagram illustrating a modified example of the GaN semiconductor device according to the first embodiment of the present disclosure;

FIG. 6 is a graph showing an example of temperature dependence of I-V characteristics in a linear region and a saturated region of a lateral MOSFET for temperature detection;

FIG. 7 is a cross-sectional view illustrating a configuration example of a GaN semiconductor device according to a second embodiment of the present disclosure;

FIG. 8 is a circuit diagram illustrating the configuration example of the GaN semiconductor device according to the second embodiment of the present disclosure;

FIG. 9 is a cross-sectional view illustrating a modified example of the GaN semiconductor device according to the second embodiment of the present disclosure;

FIG. 10 is a circuit diagram illustrating the modified example of the GaN semiconductor device according to the second embodiment of the present disclosure; and

FIG. 11 is a cross-sectional view illustrating a configuration example of a GaN semiconductor device according to a third embodiment of the present disclosure.

### DETAILED DESCRIPTION

Some embodiments according to the present disclosure are descried below.

In the following explanations regarding the drawings, the same or similar components are denoted by the same or similar reference numerals. The drawings are illustrated schematically, and relationships between thicknesses and planar dimensions, and proportions of the thicknesses of the respective members are not drawn to scale. The specific thicknesses and dimensions therefore should be determined in accordance with the explanations below. It should also be understood that the relationships or proportions of the dimensions between the drawings can differ from each other.

The following explanations may refer to the respective directions as an X-axis direction, a Y-axis direction, and a Z-axis direction. For example, the X-axis direction and the Y-axis direction are each a direction parallel to a front surface 10a of a GaN substrate 10 described below. The Z-axis direction is a direction orthogonal to the front surface 10a of the GaN substrate 10. The Z-axis direction is also a thickness direction of the GaN substrate 10. The X-axis direction, the Y-axis direction, and the Z-axis are perpendicular to each other.

In the following explanations, the positive direction in the Z-axis may be referred to as an “upper side”, and the negative direction in the Z-axis may be referred to as a “lower side”. The definitions of the “upper side” and the “lower side” do not necessarily mean the directions vertical to the ground. In other words, the respective directions of the “upper side” and the “lower side” are not limited to the gravity direction. The definitions regarding the “upper side” and the “lower side” are used only for illustration purposes to define the relative positional relationship among regions, layers, films, and a substrate, which do not limit the technical idea of the present disclosure. For example, when the observing direction of the sheet is changed by 180 degrees, the definitions of the “upper side” and the “lower side” shall be reversed.

The following embodiments are illustrated with a case in which a first conductivity-type is an N-type, and a second conductivity-type is a P-type. The respective embodiments, however, may employ the opposite conductivity relation so as to define the first conductivity-type as a P-type and the second conductivity-type as an N-type. The signs “+” and “−” added to the signs “P” and “N” used for semiconductor regions signify that the respective semiconductor regions have either a higher impurity concentration or a lower impurity concentration than other semiconductor regions without the sign “+” or “−” added. It should be understood that the respective semiconductor regions to which the same sign “P” (or the same sign “N”) is added do not necessarily or strictly have the same impurity concentration.

### First Embodiment

### <Entire Configuration Example>

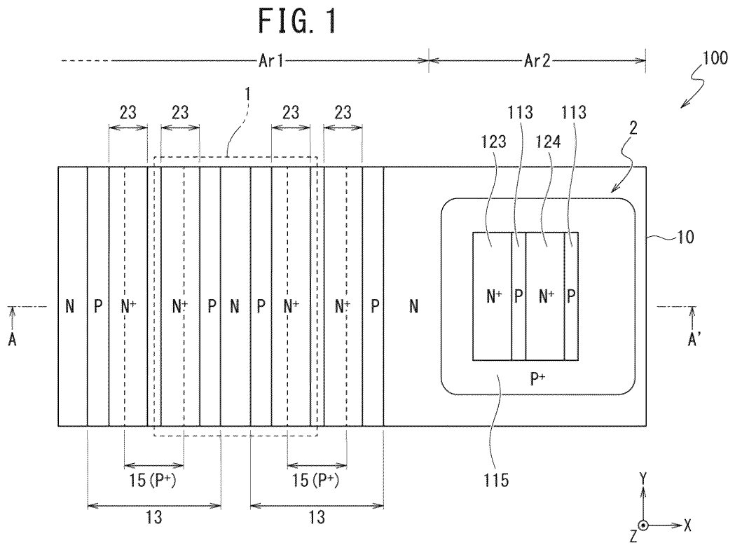

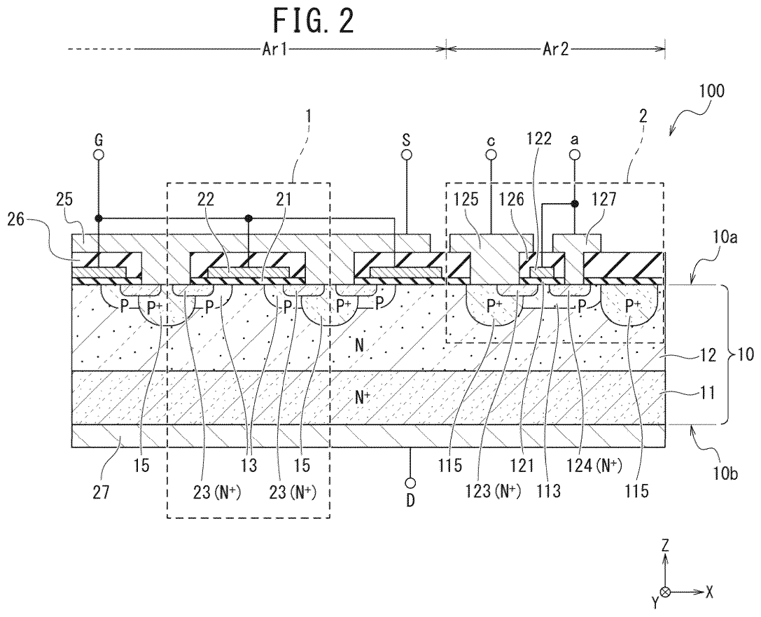

FIG. 1 is a plan view illustrating a configuration example of a gallium nitride (GaN) semiconductor device 100 according to a first embodiment of the present disclosure, which is an example of a “wide bandgap semiconductor device” according to the present disclosure. FIG. 2 is a cross-sectional view of the configuration example of the GaN semiconductor device 100 according to the first embodiment of the present disclosure, illustrating the cross section taken along line A-A′ in the plan view of FIG. 1.

The GaN semiconductor device 100 illustrated in FIG. 1 and FIG. 2 is a power device. As illustrated in FIG. 1 and FIG. 2, the GaN semiconductor device 100 includes a GaN substrate 10, which is an example of a “substrate mainly including a wide bandgap semiconductor” according to the present disclosure, having a front surface 10a and a rear surface 10b, a plurality of vertical metal-oxide-semiconductor field-effect transistors (MOSFETs) 1 provided in a first region Ar1 of the GaN substrate 10, and a lateral MOSFET 2 for temperature detection provided in a second region Ar2 of the GaN substrate 10.

The plural vertical MOSFETs 1 are repeatedly arranged in one direction, which is an X-axis direction, for example. Each of the vertical MOSFETs 1 is a repeated unit structure, and the plural unit structures are aligned in one direction. The vertical MOSFETs 1 are each a main transistor of the GaN semiconductor device 100 that is a power device.

The lateral MOSFET 2 for temperature detection is arranged toward the front surface 10a in the second region Ar2 of the GaN substrate 10. The lateral MOSFET 2 for temperature detection is a single MOSFET, for example, which differs from the vertical MOSFETs 1. The second region Ar2 is located adjacent to the first region Ar1. The second region Ar2 has a smaller area than the first region Ar1 in a planar view in the thickness direction of the GaN substrate 10, which is a Z-axis direction, for example.

As illustrated in FIG. 1 and FIG. 2, the GaN substrate 10 includes a GaN single-crystal substrate 11 of N⁺-type, and a GaN layer 12 of N-type deposited on the GaN single-crystal substrate 11. The GaN single-crystal substrate 11 is a c-plane GaN single-crystal substrate of N⁺-type, for example. The N-type impurity ions included in the GaN single-crystal substrate 11 are one or more of silicon (Si), oxygen (O), and germanium (Ge). For example, the GaN single-crystal substrate 11 includes Si as the N-type impurity ions, and an impurity concentration of Si in the GaN single-crystal substrate 11 is 5×10¹⁷ cm⁻³ or greater.

The GaN single-crystal substrate 11 may be a low-dislocation freestanding substrate with a dislocation density of less than 1×10⁷ cm⁻². The GaN layer 12 provided on the GaN single-crystal substrate 11 also has a low dislocation density when the GaN single-crystal substrate 11 is the low-dislocation freestanding substrate. The use of the low-dislocation freestanding substrate can also lead to a decrease in leakage current in the power device regardless of whether the power device having a large area is formed in the GaN substrate 10. A manufacturing apparatus thus enables the manufacture of power devices at a high non-defect ratio. This can further prevent the implanted impurity ions from being diffused deeply along the dislocation in annealing.

The GaN layer 12 is a single-crystal GaN layer epitaxially grown on one of the surfaces of the GaN single-crystal substrate 11. The GaN layer 12 is formed such that N-type impurity ions are doped during the process of epitaxial growth. The N-type impurity ions are Si, for example. The GaN layer 12 includes Si with an impurity concentration in a range of about 1×10¹⁵ cm⁻³ or greater and 5×10¹⁶ cm⁻³ or less, for example.

### <Configuration Example of Main Transistor>

The respective vertical MOSFETs 1 include a well region 13 of P-type provided toward the front surface 10a of the GaN substrate 10, namely, on the front surface side of the N-type GaN layer 12, and a contact region 15 of P⁺-type having a higher impurity concentration than the well region 13. The respective vertical MOSFETs 1 further include a gate insulating film 21 provided on the front surface 10a of the GaN substrate 10, a gate electrode 22 provided on the gate insulating film 21, a source region 23 provided toward the front surface 10a of the GaN substrate 10, a source electrode 25 provided on the front surface 10a of the GaN substrate 10 so as to be in contact with the source region 23 and the contact region 15, an insulating film 26, such as a SiO₂ film, arranged between the gate electrode 22 and the source electrode 25, and a drain electrode 27 provided on the rear surface 10b side of the GaN substrate 10 so as to be in contact with the N⁺-type GaN single-crystal substrate 11.

The well region 13 is a P-type layer formed such that P-type impurity ions such as Mg are implanted to the front surface 10a of the GaN substrate 10 and then activated by annealing. The well region 13 includes, for example, Mg as the P-type impurity ions at an impurity concentration in a range of about 1×10¹⁷ cm⁻³ or greater and 3×10¹⁸ cm⁻³ or less. The well region 13 is deposited to have a surface at the same level as the front surface 10a of the GaN substrate 10. The surface of the well region 13 is in contact with the gate insulating film 21. A channel of the respective vertical MOSFETs 1 is formed around the surface of the well region 13 in contact with the gate insulating film 21.

The source region 23 is an N⁺-type layer formed such that N-type impurity ions, such as Si and O, are implanted to the front surface 10a of the GaN substrate 10 and then activated by annealing. The source region 23 includes, for example, Si as the N-type impurity ions at an impurity concentration in a range of about 1×10¹⁹ cm⁻³ or greater and 5×10²⁰ cm⁻³ or less. The source region 23 is provided in the well region 13 located under both sides of the gate electrode 22 so as to have a surface at the same level as the front surface 10a of the GaN substrate 10. The source region 23 is arranged inside the well region 13 so as to be in contact with the well region 13.

The contact region 15 is a P⁺-type layer formed such that P-type impurity ions such as Mg are implanted to the front surface 10a of the GaN substrate 10 and then activated by annealing. The contact region 15 includes, for example, Mg as the P-type impurity ions at an impurity concentration in a range of about 3×10¹⁸ cm⁻³ or greater and 1×10²¹ cm⁻³ or less, and preferably, in a range of about 1×10¹⁹ cm⁻³ or greater and 2×10²⁰ cm⁻³ or less, for example.

The contact region 15 is deposited to have a surface at the same level as the front surface 10a of the GaN substrate 10. The contact region 15 is in contact with the well region 13 and is also in contact with the source region 23. The contact region 15 is provided to have a greater depth from the front surface 10a of the GaN substrate 10 than the well region 13.

The well region 13 is in contact with the source electrode 25 through the contact region 15. The well region 13 is thus set to a potential of the source electrode 25, which is a reference potential, such as a ground potential (GND).

The gate insulating film 21 is a SiO₂ film, for example. Instead, the gate insulating film 21 may be a single film of any of an Al₂O₃ film, a SiON film, an AlSiO film, or an AlON film, or may be a stacked film including at least two of the films described above. The gate insulating film 21 has a thickness in a range of 50 nanometers or greater and 150 nanometers or smaller, and in particular, 100 nanometers, for example.

The gate electrode 22 is located next to a region in which a channel is formed (referred to below as a “channel region”) with the gate insulating film 21 interposed. The gate electrode 22 includes metal or an alloy. For example, the gate electrode 22 is a metal electrode including titanium nitride (TiN), tungsten nitride (WN), titanium silicide (TiSi), tungsten silicide (WSi), or tungsten (W). The gate electrode 22 is connected to a gate pad (a gate terminal) G.

The source electrode 25 is in ohmic contact with each of the N⁺-type source region 23 and the P⁺-type contact region 15. The drain electrode 27 is in ohmic contact with the other surface of the N⁺-type GaN single-crystal substrate 11, which is the surface opposite to the side in contact with the GaN layer 12.

The source electrode 25 and the drain electrode 27 each include Al, an Al—Si alloy, Ni, a Ni alloy, a Ti—Al alloy, a Ni—Au alloy, or the like. The source electrode 25 may be provided with a barrier metal layer between the source electrode 25 and the source electrode 23. The drain electrode 27 may be provided with a barrier metal layer between the drain electrode 27 and the N⁺-type GaN single-crystal substrate 11. The barrier metal layer may include titanium (Ti).

That is, the source electrode 25 and the drain electrode 27 may be a stacked layer of a Ti layer and an Al layer, or a stacked layer of a Ti layer and an Al—Si alloy layer. The source electrode 25 may be an electrode serving also as a source pad (a source terminal) S, or may be an electrode provided separately from the source pad S. The drain electrode 27 may be an electrode serving also as a drain pad (a drain terminal) D (not illustrated), or may be an electrode provided separately from the drain pad D.

### <Transistor for Temperature Detection>

The lateral MOSFET 2 for temperature detection includes a well region 113 of P-type provided toward the front surface 10a of the GaN substrate 10, namely, on the front surface side of the N-type GaN layer 12, and a contact region 115 of P⁺-type, which is an example of an “impurity region” in the present disclosure, having a higher P-type impurity concentration than the well region 113. The lateral MOSFET 2 for temperature detection further includes a gate insulating film 121 provided on the front surface 10a of the GaN substrate 10, a gate electrode 122 deposited on the gate insulating film 121, a source region 123 of N⁺-type and a drain region 124 of N⁺-type provided toward the front surface 10a of the GaN substrate 10, a source electrode 125 provided on the front surface 10a of the GaN substrate 10 so as to be in contact with the source region 123 and the contact region 115, an insulating film 126, such as a SiO₂ film, arranged between the gate electrode 122 and the source electrode 125 and between the gate electrode 122 and a drain electrode 127, and the drain electrode 127 provided on the front surface 10a side of the GaN substrate 10 so as to be in contact with the drain region 124.

The P-type well region 113 is formed, for example, simultaneously in the same process as the P-type well region 13 included in the vertical MOSFET 1 serving as a main transistor, and has the configuration common to the P-type well region 13. Similarly, the P⁺-type contact region 115 is formed, for example, simultaneously in the same process as the P⁺-type contact region 15 included in the vertical MOSFET 1, and has the configuration common to the P⁺-type contact region 15.

The gate insulating film 121 is formed, for example, simultaneously in the same process as the gate insulating film 21 included in the vertical MOSFET 1, and has the configuration common to the gate insulating film 21.

The gate electrode 122 is formed, for example, simultaneously in the same process as the gate electrode 22 included in the vertical MOSFET 1, and has the configuration common to the gate electrode 22. The gate electrode 122 thus includes metal or an alloy. For example, the gate electrode 122 is a metal electrode including titanium nitride (TiN), tungsten nitride (WN), titanium silicide (TiSi), tungsten silicide (WSi), or tungsten (W).

The source region 123 and the drain region 124 are formed, for example, simultaneously in the same process as the N⁺-type source region 23 included in the vertical MOSFET 1, and have the configuration common to the N⁺-type source region 23.

The source electrode 125 is formed, for example, simultaneously in the same process as the source electrode 25 included in the vertical MOSFET 1, and has the configuration common to the source electrode 25. The source electrode 125 is in contact with the N⁺-type source region 123 and the P⁺-type contact region 115, which is an ohmic contact, for example. The source electrode 125 may be an electrode serving also as a source pad for temperature detection (a source terminal) c, or may be an electrode provided separately from the source pad c.

The drain electrode 127 is formed simultaneously in the same process as the source electrode 125, and has the configuration common to the source electrode 125. The drain electrode 127 is in ohmic contact with the N⁺-type drain region 124. The drain electrode 127 may be an electrode serving also as a drain pad for temperature detection (a drain terminal) a, or may be an electrode provided separately from the drain pad a.

The P⁺-type contact region 115 has a greater depth from the front surface 10a of the GaN substrate 10 than the P-type well region 113. As illustrated in FIG. 1 and FIG. 2, the P⁺-type contact region 115 is arranged to surround the P-type well region 113 in the planar view in the thickness direction of the GaN substrate 10, which is the Z-axis direction, for example. The arrangement of the P⁺-type contact region 115 can suppress, for example, a spread of a depletion layer from the vertical MOSFET 1 serving as a main transistor toward the well region 113. Further, this structure can minimize an area of a part inside the P-type well region 113 having a high potential if a transient current flows through the P-type well region 113 upon the spread of the depletion layer.

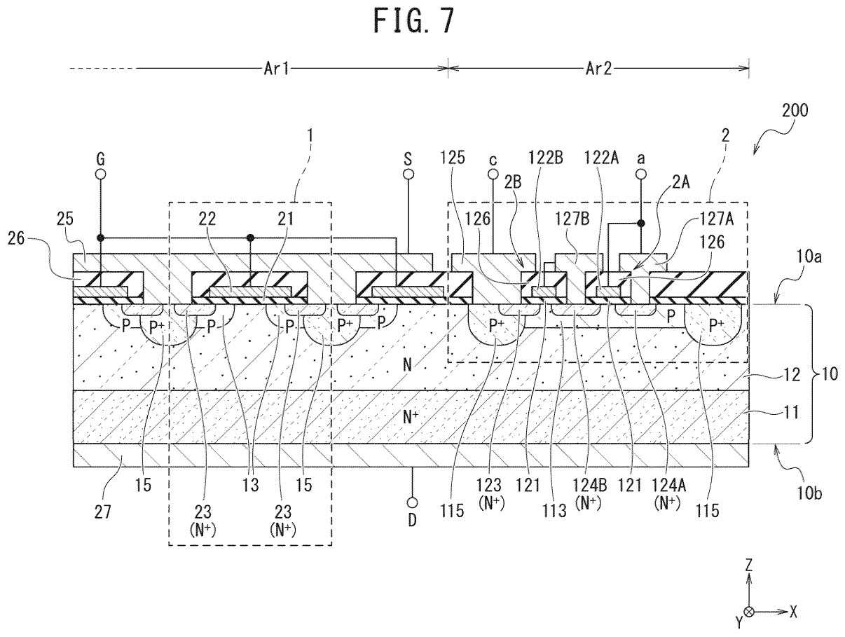

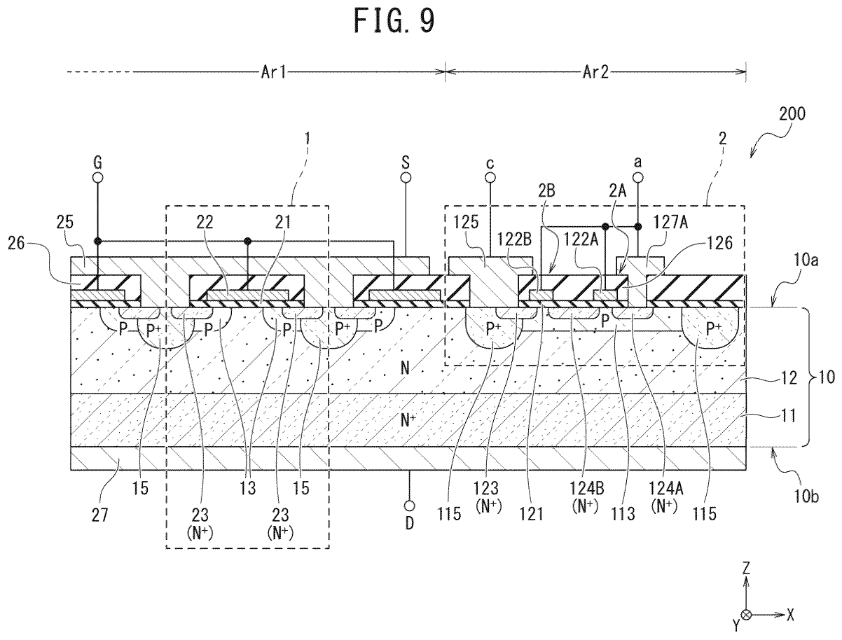

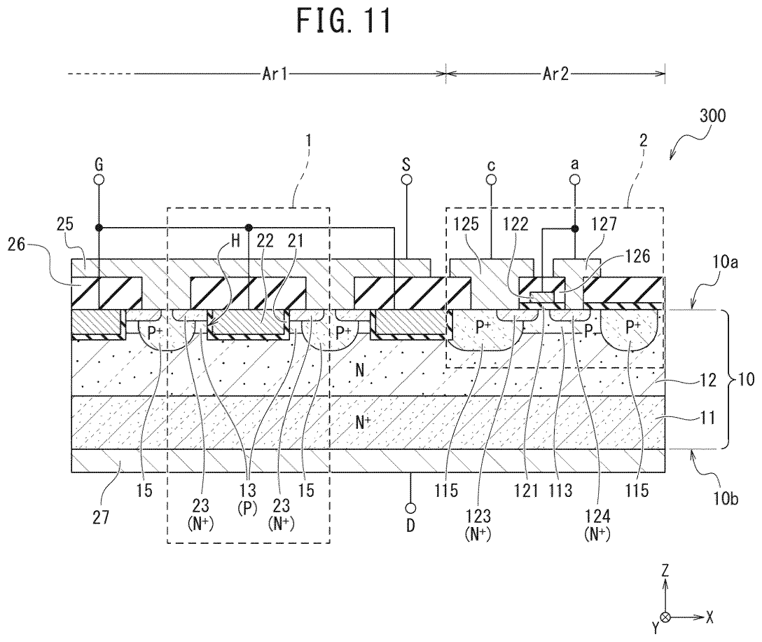

While FIG. 2 and each of FIG. 7, FIG. 9, and FIG. 11 described below illustrate the case in which the P⁺-type contact region 115 is provided to have a greater depth from the front surface 10a of the GaN substrate 10 than the P-type well region 113, the present embodiment is not limited to this case. The P⁺-type contact region 115 may have a shallower depth than the well region 113. The P⁺-type contact region 115 preferably has a greater depth than the P-type well region 113, but may have a shallower depth than the P-type well region 113 if hard to have a greater depth than the P-type well region 113 when formed by ion implantation.

### <Method of Temperature Detection>

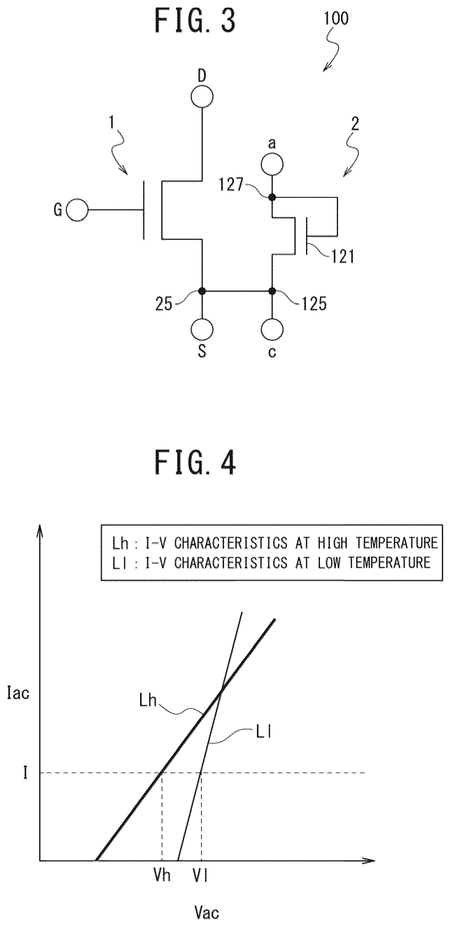

FIG. 3 is a circuit diagram illustrating a configuration example of the GaN semiconductor device 100 according to the first embodiment of the present disclosure. As illustrated in FIG. 2 and FIG. 3, the gate electrode 122 of the lateral MOSFET 2 for temperature detection is short-circuited (electrically connected) to the drain electrode 127 of the lateral MOSFET 2, and has the same potential as the drain electrode 127. The lateral MOSFET 2 causes a current Iac to flow between the drain pad a and the source pad c (flow between the drain and the source ac), so as to measure a voltage Vac between the drain and the source ac when the current Iac reaches a predetermined value.

FIG. 4 is a graph showing an example of temperature dependence of current-voltage characteristics (also referred to below as “I-V characteristics”) in a linear region of the lateral MOSFET 2 for temperature detection. The axis of abscissas in FIG. 4 shows the voltage Vac between the drain and the source ac, and the axis of ordinates shows the current Iac flowing between the drain and the source ac.

As shown in FIG. 4, the I-V characteristics in the linear region indicate a straight state and have temperature dependence. An inclination of a straight line Lh showing the I-V characteristics at a high temperature is different from an inclination of a straight line L1 at a low temperature. Therefore, as indicated by the broken line parallel to the axis of abscissas in FIG. 4, causing a current I of a predetermined value to flow between the drain and the source ac to measure the voltage Vac between the drain and the source ac can detect the temperature of the GaN substrate 10 provided with the lateral MOSFET 2.

For example, during the flow of the current I with the predetermined value between the drain and the source ac, the voltage Vh is measured at a high temperature, while the voltage VI is measured at a low temperature. When the constant current I flows in the linear region between the drain and the source ac in the lateral MOSFET 2, a relation of 1:1 is fulfilled between the temperature and the value of the voltage Vac between the drain and the source ac. This can detect the temperature of the GaN substrate 10 provided with the lateral MOSFET 2 with high accuracy in accordance with the measured value of the voltage Vac.

The current Iac caused to flow during the detection of the temperature is preferably set to a value easy to detect the temperature. For example, the current Iac is preferably set to a value not passing through a point at which the straight line Lh and the straight line L1 indicated in FIG. 4 intersect with each other because a temperature difference is not easy to detect, namely, the temperature-detection sensitivity is low at a value adjacent to the point at which the straight line Lh and the straight line L1 intersect with each other. Therefore, the current Iac is preferably set to a value avoiding the point at which the straight line Lh and the straight line L1 intersect with each other.

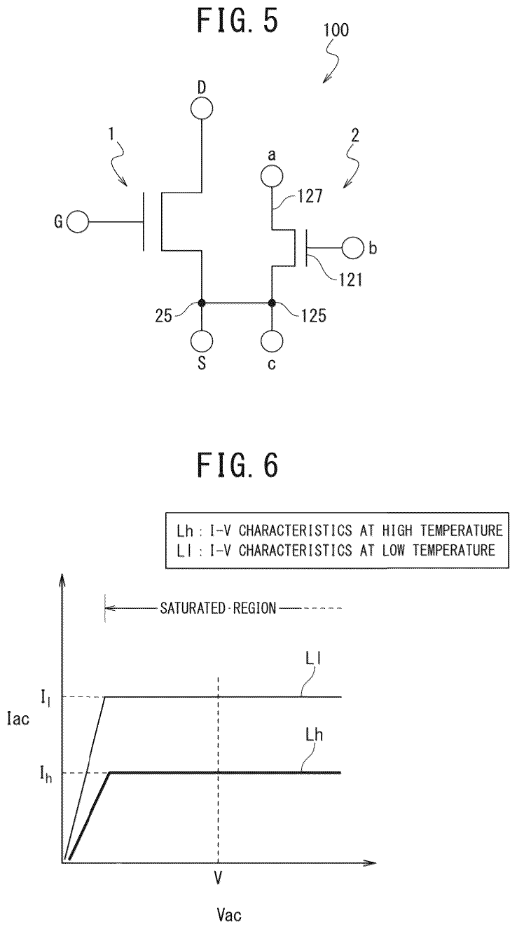

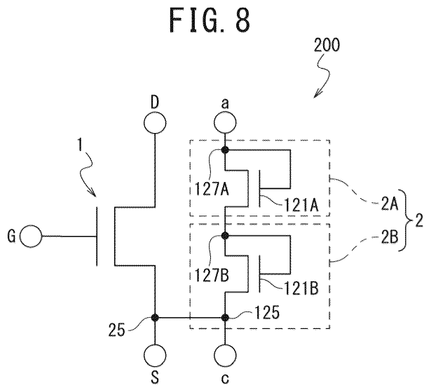

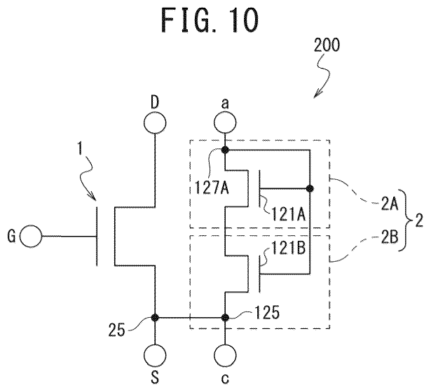

While FIG. 3 illustrates the case in which the source electrode 25 of the vertical MOSFET 1 serving as a main transistor and the source electrode 125 of the lateral MOSFET 2 for temperature detection are short-circuited, this case is an example and the respective source electrodes 25 and 125 are not necessarily connected to each other. This is also applied to a case illustrated in FIG. 5, FIG. 8, and FIG. 10 described below, and the respective source electrodes 25 and 125 do not need to be connected to each other.

### <Effects of First Embodiment>

As described above, the GaN semiconductor device 100 according to the first embodiment of the present disclosure includes the GaN substrate 10, the vertical MOSFETs 1 serving as a main transistor provided in the first region Ar1 of the GaN substrate 10, and the lateral MOSFET 2 for temperature detection provided in the second region Ar2 of the GaN substrate 10.

According to the configuration described above, the lateral MOSFET 2 for temperature detection is provided (monolithically arranged) in the same GaN substrate 10 as the vertical MOSFETs 1 serving as a main transistor, and has the same wide bandgap as the respective vertical MOSFETs 1. This configuration causes light with a short wavelength during the operation of the main vertical MOSFETs 1, so as to prevent error signals from being caused in the lateral MOSFET 2 for temperature detection if the light with the short wavelength enters the lateral MOSFET 2 for temperature detection. The lateral MOSFET 2 for temperature detection thus can detect the temperature of the GaN substrate 10 with high accuracy even during the operation of the main vertical MOSFETs 1.

The second region Ar2 provided with the lateral MOSFET 2 for temperature detection is preferably arranged adjacent to the first region Ar1 provided with the main vertical MOSFETs 1. This arrangement leads the temperature of the second region Ar2 to be the same (or substantially the same) as the first region Ar1. The lateral MOSFET 2 for temperature detection thus can detect, with higher accuracy, the temperature of the first region Ar1, namely, the temperature of the vertical MOSFETs 1 serving as a main transistor.

Further, the gate electrode 22 of the respective vertical MOSFETs 1 serving as a main transistor and the gate electrode 122 of the lateral MOSFET 2 for temperature detection each provided in the GaN semiconductor device 100 according to the first embodiment preferably include metal or an alloy with the same composition. This configuration enables the main vertical MOSFETs 1 to exhibit a high-speed operation. This also allows the simultaneous manufacture in the same process with regard to the gate electrode 22 of the respective vertical MOSFETs 1 serving as a main transistor and the gate electrode 122 of the lateral MOSFET 2 for temperature detection. Further, this configuration can eliminate any specific process for forming the gate electrode 122 of the lateral MOSFET 2 for temperature detection, such as a step of forming a polysilicon film and a doping step for the film, so as to the manufacturing costs accordingly.

As a comparative example, a PN diode would be formed as an element for temperature detection in a GaN substrate. This comparative example is provided with the PN diode implemented by an N-type impurity layer formed inside a P-type well region. If a main transistor is led to operate at a high-speed switching operation, some noise or error signals could be caused in the PN diode for temperature detection because of a junction charge current. Further, if a higher potential than a source is applied to the P-type well layer, a parasitic current would be caused due to a bipolar effect, which could lead to a wrong operation of the PN diode for temperature detection. In particular, a detected current value could include a large error, which would impede an accurate detection of the temperature. The accuracy of detecting the temperature could be decreased if any noise or error signals are caused in the PN diode or if the PN diode operates wrongly.

In contrast, the GaN semiconductor device 100 according to the first embodiment includes the lateral MOSFET 2 for temperature detection, instead of such a PN diode. The GaN semiconductor device 100 thus can avoid a cause of any noise or error signals or avoid any wrong operation more reliably than the comparative example, regardless of whether the respective vertical MOSFETs 1 serving a main transistor are led to operate at a high-speed switching operation.

### Modified Example of First Embodiment

FIG. 5 is a circuit diagram illustrating a modified example of the GaN semiconductor device 100 according to the first embodiment of the present disclosure. The GaN semiconductor device 100 of the modified example illustrated in FIG. 5 differs from the GaN semiconductor device 100 illustrated in FIG. 3 in that the gate electrode 122 is not short-circuited to (is electrically isolated from) the drain electrode 127, and in including a gate pad (a gate terminal) b connected to the gate electrode 122. The other configurations of the GaN semiconductor device 100 of the modified example are the same as those of the GaN semiconductor device 100 illustrated in FIG. 1 to FIG. 3.

FIG. 6 is a graph showing an example of temperature dependence of current-voltage characteristics (I-V characteristics) in a linear region and a saturated region of the lateral MOSFET 2 for temperature detection. The axis of abscissas in FIG. 6 shows the voltage Vac between the drain and the source ac, and the axis of ordinates shows the current Iac flowing between the drain and the source ac. A voltage applied to the gate electrode 122 in the lateral MOSFET 2, which is also referred to below as a “gate voltage”, is a constant voltage of a threshold Vth or greater of the lateral MOSFET 2.

As shown in FIG. 6, the I-V characteristics in the saturated region is constant regardless of the voltage Vac between the drain and the source. Under the conditions of the constant gate voltage, the current Iac flowing between the drain and the source ac is higher at a low temperature than at a high temperature. A voltage V of a preset value is then applied between the drain and the source ac, as indicated by the broken line parallel to the axis of ordinates in FIG. 6, in the state in which the gate voltage is set to the constant value of Vth or higher so as to measure the current Iac in the saturated region flowing between the drain and the source ac (also referred to below as a “saturated current”). This thus can detect the temperature of the GaN substrate 10 provided with the lateral MOSFET 2.

For example, when the voltage V of the preset value is applied between the drain and the source ac in the state in which the gate voltage is set to the constant value of Vth or higher, a saturated current Ih is measured at a high temperature, as the saturated current

Iac between the drain and the source ac, and a saturated current I1 is measured at a low temperature. A relation of 1:1 is then fulfilled between the temperature and the value of the saturated current Iac under the condition in which the gate voltage is set to the constant value of Vth or higher. The temperature of the GaN substrate 10 provided with the lateral MOSFET 2 thus can be detected with high accuracy according to the measured value of the saturated current Iac.

This modified example has substantially the same effects as the GaN semiconductor device 100 illustrated in FIG. 1 to FIG. 3. For example, the lateral MOSFET 2 for temperature detection is provided in the same GaN substrate 10 as (provided monolithically together with) the respective vertical MOSFETs 1 serving as a main transistor. The lateral MOSFET 2 for temperature detection thus can detect the temperature of the GaN substrate 10 with high accuracy regardless of whether the main vertical MOSFETs 1 are in operation.

### Second Embodiment

While the first embodiment is illustrated above with the case in which the lateral MOSFET 2 for temperature detection is a single transistor, the present disclosure is not limited to this case. The lateral MOSFET 2 for temperature detection may be implemented by a plurality of transistors instead.

FIG. 7 is a cross-sectional view illustrating a configuration example of a GaN semiconductor device 200 according to a second embodiment of the present disclosure. FIG. 8 is a circuit diagram of the configuration example of the GaN semiconductor device 200 according to the second embodiment of the present disclosure. The GaN semiconductor device 200 illustrated in FIG. 7 and FIG. 8 differs from the GaN semiconductor device 100 illustrated in FIG. 1 to FIG. 3 in the structure regarding the lateral MOSFET 2 for temperature detection. The GaN semiconductor device 200 according to the second embodiment includes the plural lateral MOSFETs 2 connected in series. The other configurations of the GaN semiconductor device 200 are the same as those of the GaN semiconductor device 100 illustrated in FIG. 1 to FIG. 3.

As illustrated in FIG. 7 and FIG. 8, the plural lateral MOSFETs 2 for temperature detection includes a first lateral MOSFET 2A and a second lateral MOSFET 2B connected in series to the first lateral MOSFET 2A, for example.

The first lateral MOSFET 2A includes a first drain region 124A of N⁺-type provided toward the front surface 10a of the GaN substrate 10, a first drain electrode 127A deposited on the front surface 10a of the GaN substrate 10 so as to be in contact with the first drain region 124A, and a first gate electrode 122A deposited on the gate insulating film 121.

The first gate electrode 122A is short-circuited to the first drain electrode 127A, and has the same potential as the first drain electrode 127A.

The second lateral MOSFET 2B includes a second drain region 124B of N⁺-type provided toward the front surface 10a of the GaN substrate 10, a second drain electrode 127B deposited on the front surface 10a of the GaN substrate 10 so as to be in contact with the second drain region 124B, a second gate electrode 122B deposited on the gate insulating film 121, the N⁺-type source region 123 provided toward the front surface 10a of the GaN substrate 10, and the source electrode 125 deposited on the front surface 10a of the GaN substrate 10 so as to be in contact with the source region 123 and the P⁺-type contact region 115. The second gate electrode 122B is short-circuited to the second drain electrode 127B, and has the same potential as the second drain electrode 127B.

The second drain region 124B of the second lateral MOSFET 2B also serves as a source region of the first lateral MOSFET 2A. The second drain electrode 127B of the second lateral MOSFET 2B also serves as a source electrode of the first lateral MOSFET 2A.

The first lateral MOSFET 2A and the second lateral MOSFET 2B have the same size, for example. In particular, the first lateral MOSFET 2A has the same gate length as the second lateral MOSFET 2B. The first lateral MOSFET 2A further has the same gate width as the second lateral MOSFET 2B.

In addition, the gate electrode 22 in the respective vertical MOSFETs 1 serving as a main transistor includes metal or an alloy with the same composition as each of the first gate electrode 122A and the second gate electrode 122B in the lateral MOSFETs 2 for temperature detection.

The GaN semiconductor device 200 according to the second embodiment has substantially the same effects as the GaN semiconductor device 100 according to the first embodiment described above. For example, the lateral MOSFETs 2 for temperature detection are provided in the same GaN substrate 10 as (provided monolithically together with) the respective vertical MOSFETs 1 serving as a main transistor, so as to detect the temperature of the GaN substrate 10 with high accuracy regardless of whether the main vertical MOSFETs 1 are in operation.

Further, the GaN semiconductor device 200 includes the first lateral MOSFET 2A and the second lateral MOSFET 2B connected in series. This structure can lead the voltage Vac for temperature detection to be doubled, so as to enhance the temperature-detection sensitivity, as compared with a case, for example, in which the lateral MOSFET 2 for temperature detection is implemented only by the first lateral MOSFET 2A.

### Modified Example of Second Embodiment

FIG. 9 is a cross-sectional view illustrating a modified example of the GaN semiconductor device 200 according to the second embodiment of the present disclosure. FIG. 10 is a circuit diagram of the modified example of the GaN semiconductor device 200 according to the second embodiment of the present disclosure. The GaN semiconductor device 200 of the modified example illustrated in FIG. 9 and FIG. 10 differs from the GaN semiconductor device 200 illustrated in FIG. 7 and FIG. 8 in that the first gate electrode and the second gate electrode are both short-circuited to the first drain electrode 127A, and further in not being provided with the second drain electrode 127B. The other configurations of the GaN semiconductor device 200 of the modified example are the same as those of the GaN semiconductor device 200 illustrated in FIG. 7 and FIG. 8.

This modified example has substantially the same effects as the GaN semiconductor device 200 illustrated in FIG. 7 and FIG. 8. For example, the respective lateral MOSFETs 2 for temperature detection are provided in the same GaN substrate 10 as (provided monolithically together with) the respective vertical MOSFETs 1 serving as a main transistor. The lateral MOSFETs 2 for temperature detection thus can detect the temperature of the GaN substrate 10 with high accuracy regardless of whether the main vertical MOSFETs 1 are in operation.

Further, the connection between the second drain electrode 127B and the second gate electrode 122B is not necessary, since the second drain electrode 127B is not provided. The configuration of the GaN semiconductor device 200 of the modified example illustrated in FIG. 9 and FIG. 10 thus can lead to a decrease in chip area more than that of the GaN semiconductor device 200 illustrated in FIG. 7 and FIG. 8.

### Third Embodiment

While the first and second embodiments are illustrated above with the case in which the respective vertical MOSFETs 1 serving as a main transistor have a planar structure, the present disclosure is not limited to this case. The vertical MOSFETs 1 may have a trench gate structure, instead of the planar structure.

FIG. 11 is a cross-sectional view illustrating a configuration example of a GaN semiconductor device 300 according to a third embodiment of the present disclosure. The GaN semiconductor device 300 illustrated in FIG. 11 differs from the GaN semiconductor device 100 illustrated in FIG. 1 to FIG. 3 in that the respective vertical MOSFETs 1 serving as a main transistor have a trench gate structure. The other configurations of the GaN semiconductor device 300 are the same as those of the GaN semiconductor device 100 illustrated in FIG. 1 to FIG. 3.

As illustrated in FIG. 11, the vertical MOSFETs 1 according to the third embodiment are provided with trenches H formed in the GaN substrate 10. The trenches H are open toward the front surface 10a of the GaN substrate 10. The trenches H are provided to have a greater depth than the P-type well region 13 so that the bottom of the respective trenches H reaches the N-type GaN layer 12.

The gate insulating film 21 and the gate electrode 22 are provided inside the respective trenches H. The side surfaces and the bottom surface inside the respective trenches H are covered with the gate insulating film 21. The gate electrode 22 is buried in the respective trenches H with the gate insulating film 21 interposed. The respective vertical MOSFETs 1 have a configuration in which a part of the P-type well region 13, opposed to the gate electrode 22 via the gate insulating film 21 provided along the inner side surfaces of the trenches H, serves as a channel region.

The GaN semiconductor device 300 according to the third embodiment has substantially the same effects as the GaN semiconductor device 100 according to the first embodiment described above. For example, the lateral MOSFET 2 for temperature detection is provided in the same GaN substrate 10 as (provided monolithically together with) the vertical MOSFETs 1 serving as a main transistor, so as to detect the temperature of the GaN substrate 10 with high accuracy regardless of whether the main vertical MOSFETs 1 are in operation.

### Other Embodiments

While the present disclosure has been described above by reference to the first to third embodiments and the respective modified examples, it should be understood that the present disclosure is not intended to limit the descriptions and the drawings composing part of this disclosure. Various alternative embodiments and modified examples will be apparent to those skilled in the art according to this disclosure. For example, the “wide bandgap semiconductor” according to the present disclosure is not limited to the case of including gallium nitride (GaN), and may include silicon carbide (SiC). Namely, the present disclosure may use a SiC substrate, instead of the GaN substrate 10.

It should be understood that the present disclosure can include various embodiments not disclosed herein, and can include at least various omissions, replacements, or modifications of the components without departing from the teaching of the first to third embodiments and the respective modified examples described above. It should also be understood that the effects described herein are illustrated merely as some examples that are not limited to the above descriptions, and the present disclosure may have any other effects not disclosed herein. Therefore, the technical scope of the present disclosure is defined only by the subject matter according to the claims reasonably derived from the foregoing descriptions.

The present disclosure can also have the following configurations.

(1) A wide bandgap semiconductor device including:

a substrate mainly including a wide bandgap semiconductor;

a vertical MOSFET serving as a main transistor provided in a first region of the substrate; and

a lateral MOSFET for temperature detection provided in a second region of the substrate.

(2) The wide bandgap semiconductor device of the above (1), wherein a gate electrode of the vertical MOSFET and a gate electrode of the lateral MOSFET include metal or an alloy having a common composition.
(3) The wide bandgap semiconductor device of the above (1) or (2), wherein a gate electrode of the lateral MOSFET is short-circuited to a drain electrode of the lateral MOSFET.
(4) The wide bandgap semiconductor device of the above (1) or (2), wherein the lateral MOSFET includes:

a first lateral MOSFET; and

a second lateral MOSFET connected in series to the first lateral MOSFET.

(5) The wide bandgap semiconductor device of the above (4), wherein:

the first lateral MOSFET includes a first drain electrode and a first gate electrode;

the second lateral MOSFET includes a second drain electrode and a second gate electrode;

the first gate electrode is short-circuited to the first drain electrode; and

the second gate electrode is short-circuited to the second drain electrode.

(6) The wide bandgap semiconductor device of the above (4), wherein:

the first lateral MOSFET includes a first drain electrode and a first gate electrode;

the second lateral MOSFET includes a second gate electrode; and

the first gate electrode and the second gate electrode are both short-circuited to the first drain electrode.

(7) The wide bandgap semiconductor device of any one of the above (1) to (6), wherein the second region has a smaller area than the first region in a planar view in a thickness direction of the substrate.
(8) The wide bandgap semiconductor device of any one of the above (1) to (7), wherein the second region is located adjacent to the first region.
(9) The wide bandgap semiconductor device of any one of the above (1) to (8), wherein:

the substrate is a first conductivity-type;

the lateral MOSFET includes
a well region of a second conductivity-type provided in the substrate,
a source region of the first conductivity-type provided in the well region, and
an impurity region of the second conductivity-type provided in the substrate so as to be in contact with the well region;

the impurity region has a higher concentration than the well region; and

a source electrode of the lateral MOSFET is in contact with the source region and the impurity region.

(10) The wide bandgap semiconductor device of the above (9), wherein:

the impurity region is provided to have a greater depth from a surface of the substrate than the well region; and

the impurity region surrounds the well region in a planar view in a thickness direction of the substrate.

(11) The wide bandgap semiconductor device of any one of the above (1) to (10), wherein the wide bandgap semiconductor includes silicon carbide (SiC) or gallium nitride (GaN).

What is claimed is:

1. A wide bandgap semiconductor device comprising:
a substrate mainly including a wide bandgap semiconductor;
a vertical MOSFET serving as a main transistor provided in a first region of the substrate; and
a lateral MOSFET for temperature detection provided in a second region of the substrate.

2. The wide bandgap semiconductor device of claim 1, wherein a gate electrode of the vertical MOSFET and a gate electrode of the lateral MOSFET include metal or an alloy having a common composition.

3. The wide bandgap semiconductor device of claim 1, wherein a gate electrode of the lateral MOSFET is short-circuited to a drain electrode of the lateral MOSFET. 4 The wide bandgap semiconductor device of claim 1, wherein the lateral MOSFET includes:
a first lateral MOSFET; and
a second lateral MOSFET connected in series to the first lateral MOSFET.

5. The wide bandgap semiconductor device of claim 4, wherein:
the first lateral MOSFET includes a first drain electrode and a first gate electrode;
the second lateral MOSFET includes a second drain electrode and a second gate electrode;
the first gate electrode is short-circuited to the first drain electrode; and
the second gate electrode is short-circuited to the second drain electrode.

6. The wide bandgap semiconductor device of claim 4, wherein:
the first lateral MOSFET includes a first drain electrode and a first gate electrode;
the second lateral MOSFET includes a second gate electrode; and
the first gate electrode and the second gate electrode are both short-circuited to the first drain electrode.

7. The wide bandgap semiconductor device of claim 1, wherein the second region has a smaller area than the first region in a planar view in a thickness direction of the substrate.

8. The wide bandgap semiconductor device of claim 1, wherein the second region is located adjacent to the first region.

9. The wide bandgap semiconductor device of claim 1, wherein:
the substrate is a first conductivity-type;
the lateral MOSFET includes
a well region of a second conductivity-type provided in the substrate,
a source region of the first conductivity-type provided in the well region, and
an impurity region of the second conductivity-type provided in the substrate so as to be in contact with the well region;
the impurity region has a higher concentration than the well region; and
a source electrode of the lateral MOSFET is in contact with the source region and the impurity region.

10. The wide bandgap semiconductor device of claim 9, wherein:
the impurity region is provided to have a greater depth from a surface of the substrate than the well region; and
the impurity region surrounds the well region in a planar view in a thickness direction of the substrate.

11. The wide bandgap semiconductor device of claim 1, wherein the wide bandgap semiconductor includes silicon carbide (SiC) or gallium nitride (GaN).
